(19) United States
(12) Patent Application Publication
(10) Pub. No.: US 2026/0245788 A1
(43) Pub. Date: Aug. 20, 2026

(54) Magnetic Device Having Shielding Layer

(71) Applicant: Cyntec Co., Ltd., HSINCHU COUNTY (TW)

(72) Inventors: Chi-Hsun LEE, HSINCHU COUNTY (TW); Min-Feng CHUNG, HSINCHU COUNTY (TW)

(21) Appl. No.: 19/646,604

(22) Filed: Apr. 14, 2026

Related U.S. Application Data
(63) Continuation of application No. 17/508,935, filed on Oct. 22, 2021, now abandoned.
(60) Provisional application No. 63/104,530, filed on Oct. 23, 2020.

(51) Int. Cl. H01F 27/29; H01F 27/02; H01F 27/24; H01F 27/26; H01F 27/28; H01F 27/36; H01F 41/00; H01F 41/02; H01F 41/04; H10D 1/20; H10W 90/00

(52) U.S. Cl. CPC H01F 27/29; H01F 27/022; H01F 27/24; H01F 27/266; H01F 27/2804; H01F 27/2823; H01F 27/288; H01F 27/363; H01F 41/005; H01F 41/02; H01F 41/04; H10D 1/20; H10W 90/00

(57) ABSTRACT

At least one shielding layer made of conductive material is formed on a body of an inductor, wherein at least one portion of the top surface of the body is exposed from the shielding layer, so as to provide an exhaust channel for moisture inside the body to leak to the outside of the body, thereby preventing the residual moisture from deforming the inductor due to thermal expansion.

### CROSS-REFERENCES TO RELATED APPLICATIONS

This application is a Continuation of U.S. Patent Application No. 17/508,935 filed on October 22, 2021, which claims the benefit of U.S. Provisional Patent Application No. 63/104,530 filed Oct. 23, 2020, which is hereby incorporated by reference herein and made a part of specification.

### BACKGROUND OF THE INVENTION

### I. Field of the Invention

The present disclosure relates to a magnetic device, and in particular, to a magnetic device having a shielding layer for reducing EMI.

### II. Description of Related Art

As applications of electronic circuits move toward higher frequency and miniaturization, the distance between electronic components of a system becomes closer and closer, as a result, the electromagnetic interference (EMI) problem is becoming more and more serious.

Conventional magnetic devices are often shielded by a metal casing made of a folded plate, which bears higher cost and larger size.

Therefore, a better solution is needed to resolve the above-mentioned issues.

### SUMMARY OF THE INVENTION

In one embodiment of the present disclosure, a magnetic device is disclosed, wherein the magnetic device comprises: a body, having a top surface; a first conductive layer, a second conductive layer, and an electrode structure. The first conductive layer is formed on the body, wherein the first conductive layer covers the top surface of the body for shielding the magnetic device. The first conductive layer comprises Ag. The second conductive layer is formed on the first conductive layer for shielding the magnetic device. At least one portion of the top surface of the body is exposed from the first conductive layer so as to provide an exhaust channel for moisture inside the body to leak to the outside of the body. The electrode structure is disposed on a bottom surface of the body and comprises a first electrode, a second electrode and a third electrode between the first electrode and the second electrode, wherein the third electrode is electrically connected to the first conductive layer.

In one embodiment of the present disclosure, a magnetic device is disclosed, wherein the magnetic device comprises: a body, having a top surface and a lateral surface; a first conductive layer, a second conductive layer, and an electrode structure. The first conductive layer is formed on the body, wherein the first conductive layer covers the top surface and the lateral surface of the body for shielding the magnetic device, and the first conductive layer is an Ag layer. The second conductive layer is formed on the first conductive layer for shielding the magnetic device. The first conductive layer covers at least 90% of the total area of the lateral surface of the body, wherein at least one portion of the lateral surface of the body is exposed from the first conductive layer so as to provide an exhaust channel for moisture inside the body to leak to the outside of the body. The electrode structure is disposed on a bottom surface of the body and comprising a first electrode, a second electrode and a third electrode between the first electrode and the second electrode, wherein the third electrode is electrically connected to the first conductive layer.

In order to make the aforementioned and other features and advantages of the present disclosure more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is an enlarged view illustrating a magnetic device having a shielding layer to encapsulating a body of the magnetic device according to one embodiment of the present disclosure.

FIG. 1B is an enlarged view illustrating a magnetic device having a shielding layer to encapsulating a body of the magnetic device according to one embodiment of the present disclosure.

FIG. 1C is a top view of the magnetic device with one portion of the top surface of the body of the magnetic device is not covered by the shielding layer.

FIG. 1D is a top view of the magnetic device with two portions of the top surface of the body of the magnetic device is not covered by the shielding layer.

FIG. 1E is a side view of the magnetic device with one portion of a lateral surface of the body of the magnetic device is not covered by the shielding layer.

FIG. 1F is a side view of the magnetic device with two portions of a lateral surface of the body of the magnetic device is not covered by the shielding layer.

FIG. 1G is a cross-sectional view illustrating a plurality of shielding layers to encapsulating a body of the magnetic device according to one embodiment of the present disclosure.

FIG. 1H illustrates an electrode structure of the magnetic device according to one embodiment of the present disclosure.

FIG. 1I illustrates an electrode structure of the magnetic device according to one embodiment of the present disclosure.

FIG. 2A illustrates a method for forming the magnetic device according to one embodiment of the present disclosure.

FIG. 2B illustrates a method for forming the magnetic device according to one embodiment of the present disclosure.

FIG. 2C illustrates a method for forming the magnetic device according to one embodiment of the present disclosure.

FIG. 2D illustrates a method for forming the magnetic device according to one embodiment of the present disclosure.

FIG. 2E illustrates a method for forming the magnetic device according to one embodiment of the present disclosure.

FIG. 3 is a chart to illustrate the leakage level of the magnetic field of the magnetic device based on different shielding layers according to one embodiment of the present disclosure.

FIG. 4 is a chart to illustrate the B field and E field based on different opening holes.

### DESCRIPTION OF EMBODIMENTS

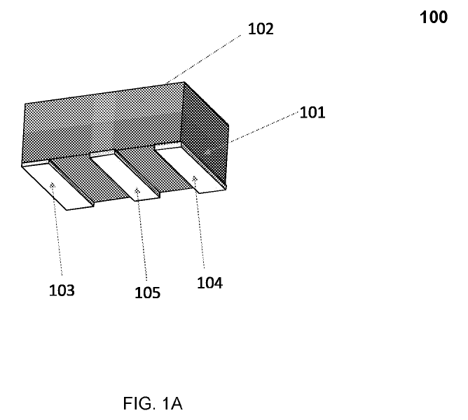

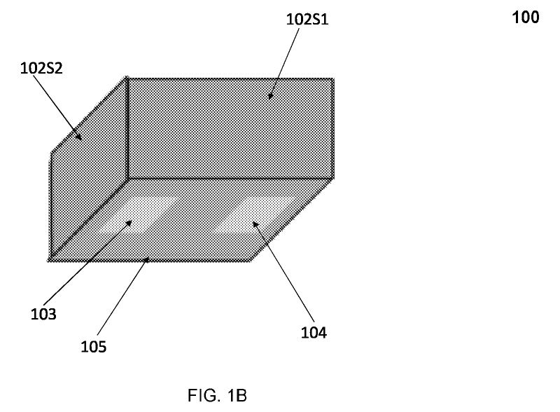

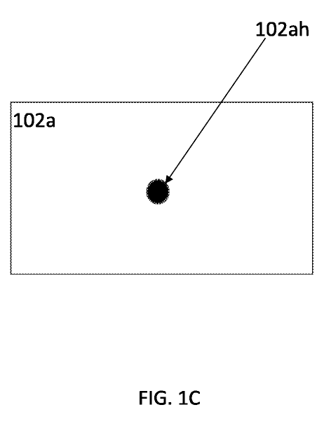

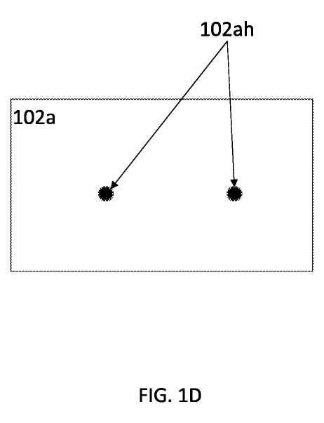

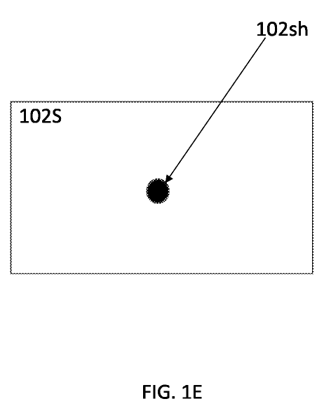

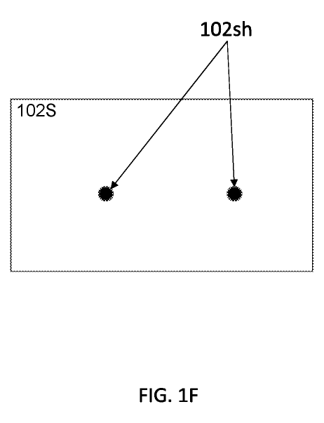

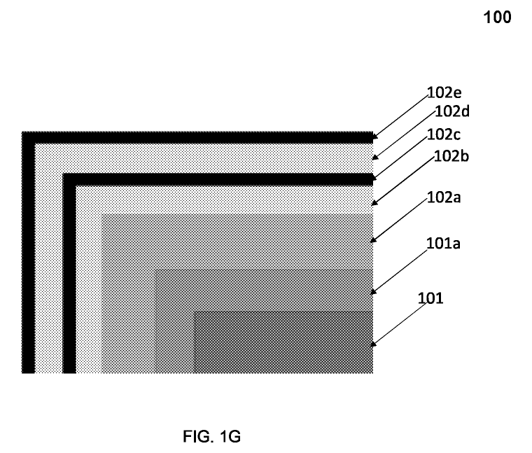

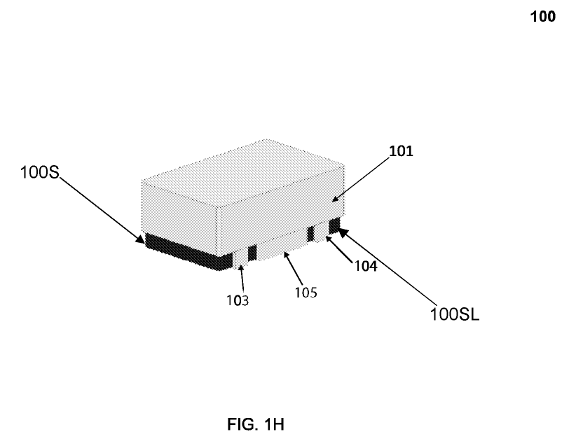

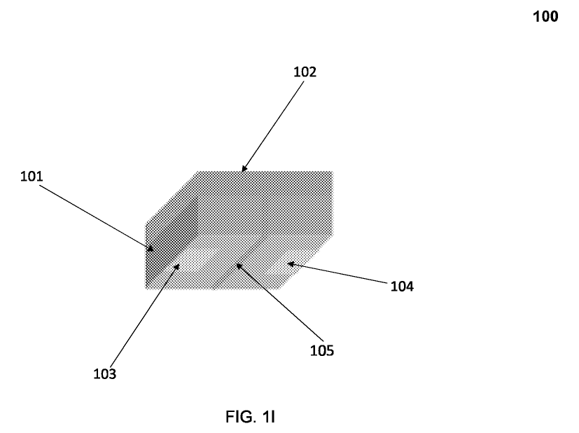

FIG. 1A depicts an enlarged cross-sectional view of a magnetic device 100 according to one embodiment of the present disclosure, wherein the magnetic device 100 comprises a body 101; and a first conductive layer 102, wherein the first conductive layer 102 is formed on the body 101 for shielding the magnetic device 100 for reducing leakage of magnetic flux generated by the magnetic device 100 so as to reduce electromagnetic interference in a system, wherein the first conductive layer 102 covers at least the top surface of the body 101 of the magnetic device 100, wherein at least one portion of the top surface of the body 101 is exposed from the first conductive layer 102, so as to provide an exhaust channel for moisture inside the body to leak to the outside of the body, thereby preventing the residual moisture from deforming the inductor due to thermal expansion.

In one embodiment, the at least one first conductive layer 102 covers the top surface of the body 101 and extends to a plurality of lateral surfaces 102S1, 102S2 of the body 101, as shown in FIG. 1B.

In one embodiment, the first conductive layer covers at least 90% of the total area of the top surface 102a of the body 101, as shown in FIG. 1C, with one portion 102ah is not covered by the first conductive layer 102.

In one embodiment, the first conductive layer covers at least 90% of the total area of the top surface 102a of the body 101, as shown in FIG. 1D, with two separated portions 102ah that are not covered by the first conductive layer 102.

In one embodiment, the first conductive layer covers at least 93% of the total area of the top surface 102a of the body 101, with one portion 102ah that is not covered by the first conductive layer 102.

In one embodiment, the first conductive layer extends to a lateral surface 102S of the body 101, wherein the first conductive layer 102 covers at least 90% of the total area of the lateral surface 102S of the body 101, as shown in FIG. 1E, with one portion 102sh that is not covered by the first conductive layer 102.

In one embodiment, the first conductive layer extends to a lateral surface 102S of the body 101, wherein the first conductive layer 102 covers at least 93% of the total area of the lateral surface 102S of the body 101, as shown in FIG. 1F, with two separated portions 102sh is not covered by the first conductive layer 102.

Please note that the present disclosure is not limited to number of portions that are not cover by the first conductive layer 102 on the top surface of the body 101 of the magnetic device 100; and the present disclosure is not limited to number of portions that are not cover by the first conductive layer 102 on the lateral surface of the body 101 of the magnetic device 100. In addition, the present disclosure is not limited to the shape of each said portion.

In one embodiment, the at least one first conductive layer 102 covers the top surface of the body 101 and extends to at least one lateral surface of the body.

In one embodiment, the at least conductive layer 102 is made of metal that is electroplated on the body for shielding the magnetic device 100.

In one embodiment, the at least conductive layer 102 is made of metal that is sputtered on the body for shielding the magnetic device 100.

In one embodiment, the at least one first conductive layer 102 is made of conductive and adhesive material that is coated on the body for shielding the magnetic device 100.

In one embodiment, the body 101 comprises an insulating layer and a magnetic body, wherein the insulating layer is disposed on the magnetic body, and the at least conductive layer is electroplated on the insulating layer for shielding the magnetic device 100.

In one embodiment, the body comprises an insulating layer and a magnetic body, wherein the insulating layer is disposed on the magnetic body, and the at least one first conductive layer is coated on the insulating layer for shielding the magnetic device.

In one embodiment, the body comprises a magnetic body, further comprising a coil disposed in the magnetic body.

In one embodiment, a metal layer made of Fe and Ni is disposed on the insulating layer.

In one embodiment, the at least one first conductive layer comprises at least one of the following metal materials: Cu, Al, Ni, Fe, Sn and Ag.

In one embodiment, the at least one first conductive layer comprises a metal layer made of Fe and Ni.

In one embodiment, the first metal layer comprising Cu has a thickness greater than 5μm.

In one embodiment, the first metal layer comprising Cu has a thickness between 5μm to 30μm.

In one embodiment, the first metal layer comprising Fe and Ni has a thickness greater than 2μm.

In one embodiment, the first metal layer comprising Fe and Ni has a thickness between 2μm to 30μm.

In one embodiment, the first metal layer has a thickness between 10μm to 20μm.

In one embodiment, a permeability of the first metal layer is greater than 500.

In one embodiment, the at least one first conductive layer comprises at least one of the following magnetic material: ferrite, alloy, Fe and Ni.

In one embodiment, the at least one first conductive layer comprises a first metal layer made of Ni and a second metal layer made of Cu, wherein the second metal layer is electroplated on the first metal layer.

In one embodiment, the at least one first conductive layer comprises a first metal layer made of Fe and Ni and a second metal layer made of Cu, wherein the second metal layer is electroplated on the first metal layer.

In one embodiment, the at least one first conductive layer comprises a first metal layer made of Cu and a second metal layer made of Fe and Ni, wherein the second metal layer is electroplated on the first metal layer.

In one embodiment, the first metal layer made of Cu has a thickness greater than 5μm and the second metal layer made of Fe and Ni has a thickness greater than 2μm.

In one embodiment, the first metal layer made of Cu has a thickness between 5μm-30μm and the second metal layer made of Fe and Ni has a thickness between 2μm-30μm.

In one embodiment, the first metal layer made of Cu has a thickness between 20μm-30μm and the second metal layer made of Fe and Ni has a thickness between 10μm-20μm.

In one embodiment, a first electrode, a second electrode and a third electrode are disposed on the bottom surface of the body, wherein the first electrode and the second electrode are electrically connected to the coil, and the third electrode is electrically connected to the at least one first conductive layer. In one embodiment, the third electrode is located between the first electrode and the second electrode. In one embodiment, the third electrode encompasses an edge of the bottom surface of the body.

FIG. 1G depicts an enlarged cross-sectional view of a magnetic device 100, wherein the magnetic device 100 comprises a body 101; and at least one first conductive layer 102, wherein the at least one first conductive layer 102 is formed on the body 101 of the magnetic device 100 for shielding the magnetic device 100 for reducing leakage of magnetic flux generated by the magnetic device 100 so as to reduce electromagnetic interference in a system, wherein the at least one first conductive layer 102 covers at least the top surface of the body 101 of the magnetic device 100.

In one embodiment, the body 101 is a magnetic body and an insulating layer 101a is disposed on the magnetic body 101, wherein at least one first conductive layer 102 is formed on the insulating layer 101a for shielding the magnetic device 100.

In one embodiment, the at least one first conductive layer 102 comprises a plurality of conductive layers 102, and the body 101 is a magnetic body, wherein an insulating layer 101a is disposed on the magnetic body 101, wherein the plurality of conductive layers 102 are formed on the insulating layer 101a for shielding the magnetic device, wherein a second conductive layer is formed on a first conductive layer for shielding the magnetic device, wherein at least one portion of the top surface of the body 101 is exposed from the first conductive layer such as a metal layer made of Ag 102a and the second conductive layer a metal layer made of Cu 102b, so as to provide an exhaust channel for moisture inside the body to leak to the outside of the body, thereby preventing the residual moisture from deforming the inductor due to thermal expansion.

In one embodiment, a metal layer made of Ag 102a is disposed on the insulating layer 101a.

In one embodiment, a metal layer made of Cu 102b is disposed on the metal layer made of Ag 102a. In one embodiment, a metal layer made of Fe and Ni 102c is disposed on the metal layer made of Cu 102b. In one embodiment, a metal layer made of Cu 102d is disposed on the metal layer made of Fe and Ni 102c. In one embodiment, a metal layer made of Fe and Ni 102e is disposed on the metal layer made of Cu 102d.

In one embodiment, a metal layer made of Cu 102b is disposed on the insulating layer 101a. In one embodiment, a metal layer made of Fe and Ni 102c is disposed on the metal layer made of Cu 102b. In one embodiment, a metal layer made of Cu 102d is disposed on the metal layer made of Fe and Ni 102c. In one embodiment, a metal layer made of Fe and Ni 102e is disposed on the metal layer made of Cu 102d.

In one embodiment, a metal layer made of Fe and Ni 102c is disposed on the insulating layer 101a. In one embodiment, a metal layer made of Cu 102b is disposed on the metal layer made of Fe and Ni 102c. In one embodiment, the metal layer made of Fe and Ni 102e is disposed on the metal layer made of Cu 102b. In one embodiment, the metal layer made of Cu 102d is disposed on the metal layer made of Fe and Ni 102e.

FIG. 1H illustrates an electrode structure of a magnetic device according to one embodiment of the present disclosure. In one embodiment, as shown in FIG. 1H, an electrode structure 100S that disposed on the bottom surface of the body 101 and comprises a first electrode 103, a second electrode 104 and a third electrode 105, wherein the third electrode 105 is electrically connected to the at least one first conductive layer for shielding the magnetic device, wherein the third electrode 105 is used for electrically connecting with a ground, and the first electrode 103 and the second electrode 104 are electrically connecting with a coil inside the body 101 of the magnetic device. As shown in FIG. 1H, the thickness of the third electrode 105 can be the same as the thickness of each of the first electrode 103 and the second electrode 104. In one embodiment, the width of the third electrode 105 is greater than the width of each of the first electrode 103 and the second electrode 104, respectively, wherein each said width is measured on a lateral surface 100SL of the electrode structure 100S as shown in FIG. 1H. In one embodiment, the width of the third electrode 105 is at least three times of the width of each of the first electrode 103 and the second electrode 104 for reducing the EMI. In one embodiment, the width of the third electrode 105 is at least four times of the width of each of the first electrode 103 and the second electrode 104 for reducing the EMI. In one embodiment, the width of each of the first electrode 103 and the second electrode 104 is between 0.1mm and 0.3 mm, and the width of the third electrode 105 is between 0.6mm and 1.0 mm. In one embodiment, the width of each of the first electrode 103 and the second electrode 104 is 0.2mm, and the width of the third electrode 105 is 0.8mm. In one embodiment, the third electrode 105 is located between the first electrode 103 and the second electrode 104. In one embodiment, the thickness of each of the first electrode 103, the second electrode 104 and the third electrode 105 is 0.2mm.

FIG. 1I illustrates an electrode structure of a magnetic device according to one embodiment of the present disclosure. In one embodiment, as shown in FIG. 1I, the first electrode 103 and the second electrode 104 are disposed on the bottom surface of the body 101 and electrically connected to a coil disposed inside the body 101, wherein the at least one first conductive layer 102 is extended from the top surface to the bottom surface through a lateral surface of the body 101, wherein an extended portion of the at least one first conductive layer that is disposed on the bottom surface of the body can be used to form the third electrode 105 for connecting with a ground.

In one embodiment, a first electrode, a second electrode, a third electrode and a fourth electrode are disposed on the bottom surface of the body, wherein the first electrode and the second electrode are electrically connected to the coil, and the third electrode and the fourth electrode are electrically connected to the at least one first conductive layer.

In one embodiment, the body comprises an insulating layer and a magnetic body, wherein the insulating layer is disposed on the magnetic body, and the at least conductive layer is electroplated on the insulating layer for shielding the magnetic device.

In one embodiment, the body comprises an insulating layer and a magnetic body, wherein the insulating layer is disposed on the magnetic body, and the at least one first conductive layer is coated on the insulating layer for shielding the magnetic device.

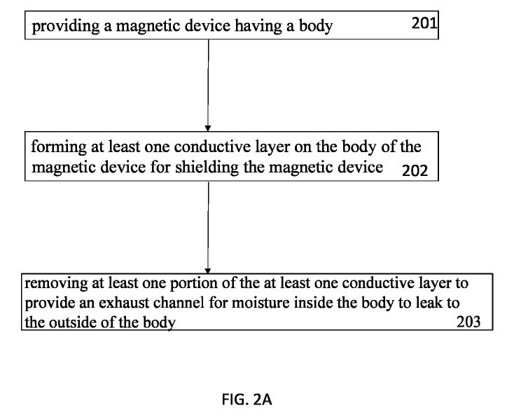

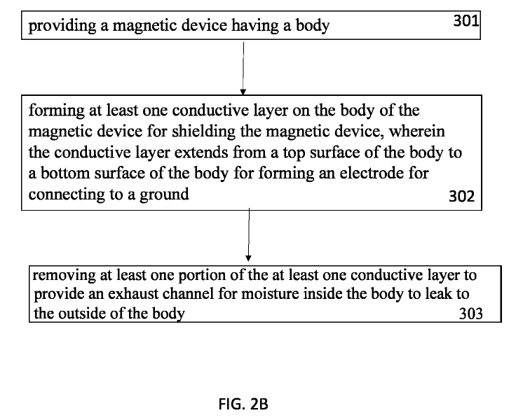

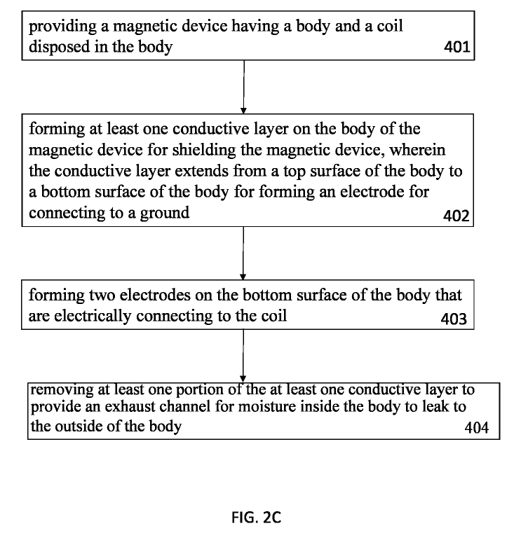

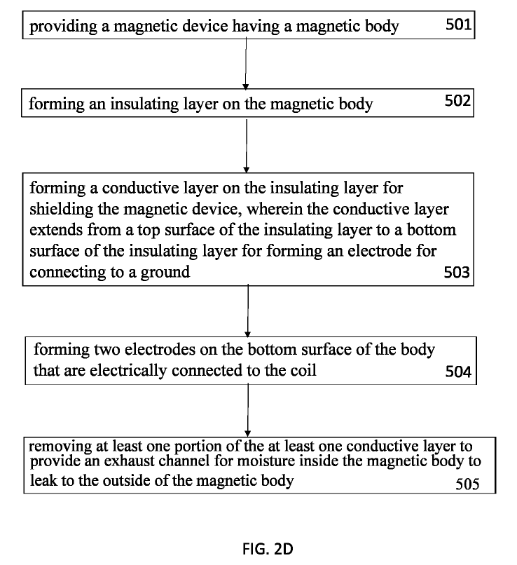

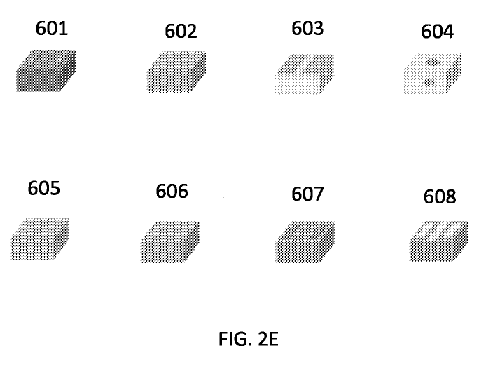

FIG. 2A illustrates a method for forming the magnetic device according to one embodiment of the present disclosure, wherein the method comprises: in step 201: providing a magnetic device having a body; in step 202: forming at least one first conductive layer on the body of the magnetic device for shielding the magnetic device, wherein the conductive layer extends from a top surface of the body to a bottom surface of the body for forming an electrode for connecting to a ground; and in step 203: removing at least one portion of the at least one first conductive layer so as to provide an exhaust channel for moisture inside the body to leak to the outside of the body, thereby preventing the residual moisture from deforming the inductor due to thermal expansion.

FIG. 2B illustrates a method for forming the magnetic device according to one embodiment of the present disclosure, wherein the method comprises: in step 301: providing a magnetic device having a body and a coil disposed in the body; in step 302: forming at least one first conductive layer on the body of the magnetic device for shielding the magnetic device, wherein the conductive layer extends from a top surface of the body to a bottom surface of the body for forming an electrode for connecting to a ground; and in step 303: removing at least one portion of the at least one first conductive layer so as to provide an exhaust channel for moisture inside the body to leak to the outside of the body, thereby preventing the residual moisture from deforming the inductor due to thermal expansion.

FIG. 2C illustrates a method for forming the magnetic device according to one embodiment of the present disclosure, wherein the method comprises: in step 401: providing a magnetic device having a body and a coil disposed in the body; in step 402: forming at least one first conductive layer on the body of the magnetic device for shielding the magnetic device, wherein the conductive layer extends from a top surface of the body to a bottom surface of the body for forming an electrode for connecting to a ground; and in step 403: forming two electrodes on the bottom surface of the body that are electrically connected to the coil; and in step 404: removing at least one portion of the at least one first conductive layer to provide an exhaust channel for moisture inside the body to leak to the outside of the body, thereby preventing the residual moisture from deforming the inductor due to thermal expansion.

FIG. 2D illustraes a method for forming the magnetic device according to one embodiment of the present disclosure, wherein the method comprises: in step 501: providing a magnetic device having a magnetic body; in step 502: forming an insulating layer on the magnetic body; and in step 503: forming a conductive layer on the insulating layer for shielding the magnetic device, wherein the conductive layer extends from a top surface of the insulating layer to a bottom surface of the insulating layer for forming an electrode for connecting to a ground; and in step 504: forming two electrodes on the bottom surface of the body that are electrically connected to the coil; and in step 505: removing at least one portion of the at least one first conductive layer so as to provide an exhaust channel for moisture inside the magnetic body to leak to the outside of the magnetic body, thereby preventing the residual moisture from deforming the inductor due to thermal expansion.

FIG. 2E illustraes a method for forming the magnetic device according to one embodiment of the present disclosure, wherein the method comprises: in step 601: providing a magnetic device having a magnetic body; in step 602: forming a first insulating layer on the magnetic body; and in step 603: forming a first conductive layer on the insulating layer for shielding the magnetic device, wherein the first conductive layer extends from a top surface of the insulating layer to a bottom surface of the insulating layer; in step 604: removing at least one portion of the at least one first conductive layer so as to provide an exhaust channel for moisture inside the magnetic body to leak to the outside of the magnetic body, thereby preventing the residual moisture from deforming the inductor due to thermal expansion. In addition, in step 605: plating Cu/Ni metal layer over the first conductive layer; in step 606: plating Cu/Ni metal layer over the first conductive layer; forming a second insulating layer over the the Cu/Ni metal layer; in step 607: remove portions of the second insulating layer to expose the electrodes; and in step 608; plating cu or printing Ag/Ni/Sn on the electrodes.

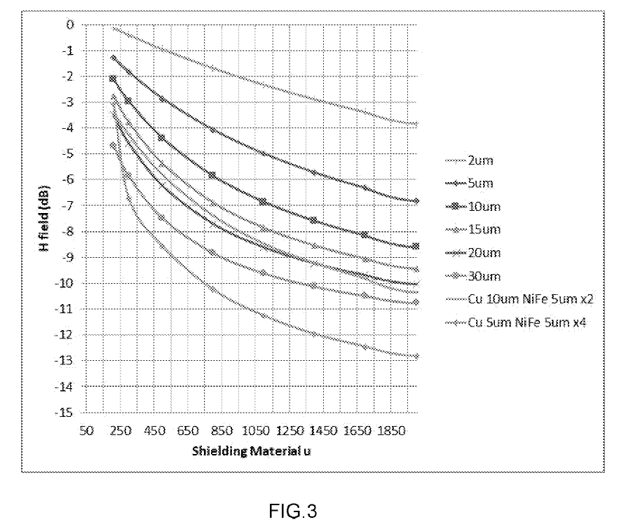

FIG. 3 is a chart to illustrate the leakage level of the magnetic field of the magnetic device based on different shielding layers according to one embodiment of the present disclosure, wherein the shielding effect can be improved by increasing the thickness of the conductive layer or by increasing the number of the conductive layers.

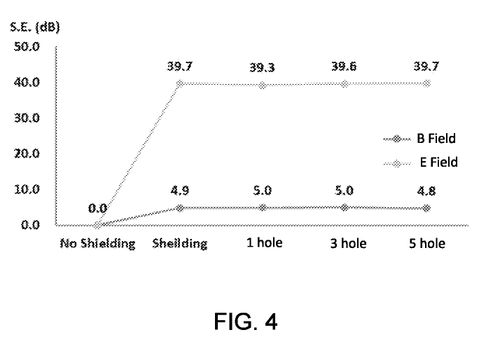

FIG. 4 is a chart to illustrate the B field and E field based on different opening holes, wherein the holes are used for providing exhaust channels to avoid residual moisture to deform the shape of the inductor, as shown in FIG. 4, the impact on the B field and E field after opening the hole is not significant.

Although the present disclosure has been described with reference to the above embodiments, it will be apparent to one of ordinary skill in the art that modifications to the described embodiment may be made without departing from the spirit of the invention. Accordingly, the scope of the invention will be defined by the attached claims, not by the above-detailed descriptions.

What is claimed is:

1. A magnetic device, comprising:
a body, having a top surface;
a first conductive layer, wherein the first conductive layer is formed on the body, wherein the first conductive layer covers the top surface of the body for shielding the magnetic device, wherein the first conductive layer comprises Ag;
a second conductive layer formed on the first conductive layer for shielding the magnetic device, wherein at least one portion of the top surface of the body is exposed from the first conductive layer and the second conductive layer and is fully surrounded by the first conductive layer and the second conductive layer on the top surface of the body so as to provide an exhaust channel for moisture inside the body to leak to an outside of the body; and
an electrode structure disposed on a bottom surface of the body and comprising a first electrode, a second electrode and a third electrode between the first electrode and the second electrode, wherein the third electrode is electrically connected to the first conductive layer.

2. The magnetic device according to claim 1, wherein the first conductive layer covers at least 90% of an total area of the top surface of the body.

3. The magnetic device according to claim 1, wherein the first conductive layer covers at least 93% of an total area of the top surface of the body.

4. The magnetic device according to claim 1, wherein the first conductive layer extends to a lateral surface of the body, wherein the first conductive layer covers at least 90% of an total area of the lateral surface of the body.

5. The magnetic device according to claim 1, wherein the first conductive layer extends to a lateral surface of the body, wherein the first conductive layer covers at least 93% of an total area of the lateral surface of the body.

6. The magnetic device according to claim 1, wherein the first conductive layer covers the top surface of the body and extends to a bottom surface of the body via a lateral surface of the body.

7. The magnetic device according to claim 1, wherein the first conductive layer covers the top surface of the body and extends to four lateral surfaces of the body.

8. The magnetic device according to claim 1, wherein the first conductive layer is made of metal that is electroplated on the body for shielding the magnetic device.

9. The magnetic device according to claim 1, wherein the first conductive layer is made of metal that is sputtered on the body for shielding the magnetic device.

10. The magnetic device according to claim 1, wherein the first conductive layer is made of conductive and adhesive material that is coated on the body for shielding the magnetic device.

11. The magnetic device according to claim 1, wherein the body is a magnetic body, wherein an insulating layer is disposed on the magnetic body, wherein the first conductive layer is formed on the insulating layer for shielding the magnetic device.

12. The magnetic device according to claim 1, wherein the second conductive layer is a Cu layer or a Fe-Ni layer.

13. The magnetic device according to claim 1, wherein the third electrode encompasses an edge of the bottom surface of the body.

14. The magnetic device according to claim 1, wherein a width of the third electrode is greater than a width of each of the first electrode and the second electrode, respectively.

15. A magnetic device, comprising:
a body, having a top surface and a lateral surface;
a first conductive layer, wherein the first conductive layer is formed on the body, wherein the first conductive layer is an Ag layer;
a second conductive layer formed on the first conductive layer for shielding the magnetic device, wherein the first conductive layer covers the top surface and the lateral surface of the body for shielding the magnetic device, wherein the first conductive layer covers at least 90% of an total area of the lateral surface of the body, wherein at least one portion of the lateral surface of the body is exposed from the first conductive layer and the second conductive layer and is fully surrounded by the first conductive layer and the second conductive layer on the lateral surface of the body so as to provide an exhaust channel for moisture inside the body to leak to an outside of the body; and
an electrode structure disposed on a bottom surface of the body and comprising a first electrode, a second electrode and a third electrode between the first electrode and the second electrode, wherein the third electrode is electrically connected to the first conductive layer.

16. The magnetic device according to claim 15, wherein the first conductive layer covers at least 93% of the total area of the lateral surface of the body.

17. The magnetic device according to claim 15, wherein the body is a magnetic body, wherein an insulating layer is disposed on the magnetic body, wherein the first conductive layer is formed on the insulating layer for shielding the magnetic device.

18. The magnetic device according to claim 15, wherein the second conductive layer is a Cu layer or a Fe-Ni layer.

19. The magnetic device according to claim 15, wherein the third electrode encompasses an edge of the bottom surface of the body.

20. The magnetic device according to claim 15, wherein a width of the third electrode is greater than a width of each of the first electrode and the second electrode, respectively.
